(19) United States
(12) Patent Application Publication
(10) Pub. No.: US 2007/0004186 A1
(43) Pub. Date: Jan. 4, 2007

(54) Film forming method

(75) Inventors: Naoki Yoshii, Nirasaki-shi (JP); Yasuhiko Kojima, Nirasaki-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 11/514,919

(22) Filed: Sep. 5, 2006

Related U.S. Application Data
(63) Continuation-in-part of application No. PCT/JP05/03340, filed on Feb. 28, 2005.

(30) Foreign Application Priority Data
Mar. 3, 2004 (JP) 2004-058449

(51) Int. Cl. H01L 21/00; G06F 19/00; C23C 16/00; H01L 21/20

(52) U.S. Cl. 438/584; 700/121; 427/248.1; 438/5

(57) ABSTRACT

A film forming method is provided for forming a thin film including a metal on a substrate by alternately supplying the substrate with a film forming material including the metal and a reducing gas. At least a part of the film forming material is dissociated or decomposed in vapor phase by plasma and supplied onto the substrate.

This application is a Continuation-In-Part Application of PCT International Application No. PCT/JP2005/003340 filed on Feb. 28, 2005, which designated the United States.

### FIELD OF THE INVENTION

The present invention relates to a method for forming a thin film containing a metal, such as a metal film and a metal nitride film; and, more particularly, to a process of forming a metal nitride film or a metal film used for a semiconductor device circuit.

### BACKGROUND OF THE INVENTION

In a wiring process of a semiconductor integrated circuit, a formation of a barrier film is necessary to suppress a Cu film from diffusing into a low dielectric interlayer insulating film (low-K film). As for the barrier film, TiN, TaN, WN, Ti, Ta, W and the like are considered to be promising materials therefor.

S. M. Rossnagel et al, in “Plasma-enhanced Atomic Layer Deposition of Ta and Ti for Interconnect Diffusion Barriers,” J. VacSci. Technol. B 18(4), July/August 2000, disclose a PE-ALD (Plasma Enhanced-Atomic Layer Deposition) method as a method for forming a metal thin film (e.g., a Ti film), which uses TiCl₄ as a source gas, H₂ as a reducing gas, and an ICP (Inductively Coupled Plasma apparatus) as an excitation source. In the conventional PE-ALD method, plasma is ignited to generate ions and radicals when the reducing gas (H₂) is supplied, while plasma is not ignited when the source material (TiCl₄) is supplied. Therefore, the source material is supplied onto a substrate as gas molecules (TiCl₄) without being decomposed. Then, the source material reacts with the gas plasma of the reducing gas, so that the molecules of the source gas are dissociated to form a thin film on the substrate.

However, in the film formation of the conventional PE-ALD method, because an amount of the metal source material species adsorbed on the substrate is one atom layer thick or less, a growth rate of the metal film is very low. Further, in the conventional PE-ALD method, a film quality and a film thickness uniformity of thus obtained thin film are not always consistent or sufficient.

Japanese Patent Laid-open Publication No. 2003-109914 discloses a method for forming a Cu film of a predetermined film thickness by using a parallel plate type plasma apparatus, wherein the Cu film is formed by supplying a Cu source gas and H₂ gas to form a Cu layer and then intermittently supplying the source gas by a manifold valve.

However, in such a method wherein the source gas and the H₂ gas as the reducing gas are supplied simultaneously to be converted into a plasma and the reducing gas is then supplied, a film formation is carried out when the source gas and the H₂ gas are converted into the plasma and the source gas and the reducing gas can not reach a bottom portion of a fine hole, so that a step coverage is poor.

### SUMMARY OF THE INVENTION

It is, therefore, an object of the present invention to provide a film forming method wherein, in case a thin film containing a metal is formed by a PE-ALD method, a film forming rate can be increased, so that a film quality and a film thickness uniformity of the obtained thin film are high, and a step coverage is good even in a fine hole. Further, it is another object of the present invention to provide a computer storage medium for storing software executable by a control computer of a film forming apparatus, which performs the above-described film forming method in such a manner that the control computer controls the film forming apparatus by executing the software.

In accordance with a first aspect of the present invention, there is provided a film forming method for forming a thin film including a metal on a substrate by alternately supplying the substrate with a film forming material including the metal and a reducing gas, wherein at least a part of the film forming material is dissociated or decomposed in gaseous state by a plasma and is supplied onto the substrate.

In accordance with a second aspect of the present invention, there is provided a film forming method for forming a thin film including a metal on a substrate, including the steps of;

(a) supplying a film forming material including the metal to the substrate;

(b) removing a residual gas in the processing chamber after the supply of the film forming material is stopped;

(c) supplying a reducing gas to the substrate in the processing chamber; and

(d) removing a residual gas in the processing chamber after the supply of the reducing gas is stopped,

wherein the thin film is formed by repeatedly performing the steps (a) to (d),

and, in the step (a), at least a part of the film forming material is dissociated or decomposed in gaseous state by a plasma and supplied onto the substrate.

In accordance with a third aspect of the present invention, there is provided a computer storage medium storing a software executable by a computer system, wherein, when a thin film including a metal is formed on a substrate by repeating the following steps of;

(a) supplying a film forming material including the metal to the substrate in a processing chamber;

(b) removing a residual gas in the processing chamber after a supply of the film forming material is stopped;

(c) supplying a reducing gas to the substrate in the processing chamber; and

(d) removing a residual gas in the processing chamber after the supply of the reducing gas is stopped,

the software controls a gas plasma in the processing chamber so that at least a part of the film forming material is dissociated or decomposed in gaseous state by the plasma and supplied onto the substrate in the step (a).

In the conventional PE-ALD method, because no plasma is generated while a film forming material including a desired metal is supplied, the film forming material is transported onto a substrate without being decomposed. Therefore, because the film forming material is not completely decomposed when the film forming material reaches the substrate, an adsorption site thereof is obstructed by large molecules of the film forming material so that an adsorption amount of a film component adsorbed on the substrate is decreased. Further, because the film forming material is adsorbed without being decomposed, when the reducing gas is supplied to react with thus adsorbed material and the film forming material is dissociated to form a film, thus dissociated chemical species may be included in the film as impurities, which makes a film quality insufficient. Further, in case that the film forming material and the reducing gas are converted into a plasma at the same time to form the film, they reach the adsorption site at the same time, which makes it difficult for them to reach a bottom portion of a fine hole.

On the contrary, in accordance with the present invention, because at least a part of the film forming material is dissociated or decomposed (hereinafter referred to simply as “dissociated”) in gaseous state by the plasma, the film forming materials reach the substrate not as itself having a large molecular size but as a precursor of the film-forming metal resulted from the dissociation of the film forming material. Therefore, a ratio of the film-forming metal adsorbed on the substrate can be increased, which makes the separation thereof difficult. That is, in case the film-forming material is an organic substance, for example, a —CH₃ group or the like is separated from its constituent molecules, and in case the film-forming material is an inorganic substance, for example, a Cl⁻ or F⁻ is separated, so that the film-forming material reaches the substrate in the state of the volumetrically smaller precursor thereof. Therefore, the percentage of the film-forming metal adsorbed on the substrate is increased, thereby making the separation thereof difficult. As a result, the film forming rate can be increased so that a throughput of a film forming process can be improved.

Further, in accordance with the present invention, at least a part of the film-forming material is dissociated in gaseous state by the plasma, so that the inclusion of the dissociated chemical species in the film on the substrate is suppressed, thus decreasing impurities in the film. When the film forming material is dissociated by the plasma, the material becomes the “volumetrically smaller precursor of the film-forming metal”. Because the precursor of the film-forming metal is densely adsorbed on a surface of the substrate, a uniformity of the film-forming metal adsorbed on the substrate is improved. As a result, the film quality and the film thickness uniformity of the thin film including the metal are improved.

Further, because only the volumetrically smaller precursor of the film-forming metal, resulted from the dissociation of the film-forming material dissociated by the plasma, is supplied onto the substrate separately from the reducing gas to be adsorbed thereon, the bottom portion of the fine hole can be reached easier than in a case where the reducing gas is supplied simultaneously, so that the step coverage in the fine hole is improved.

In the first and the second aspect of the present invention, it is preferable that the reducing gas is converted into the plasma when the reducing gas is supplied onto the substrate. Further, the plasma for dissociating a part of the film forming material may be a plasma of an inert gas.

Further, in the first aspect of the present invention, it is preferable that, after the film forming material is supplied onto the substrate, and after the reducing gas is supplied onto the substrate, the surplus film forming material and the reducing gas are removed from a top surface of the substrate.

Further, in the second aspect of the present invention, the step (b) and the step (d) may be performed by replacing an atmosphere in the processing chamber with the inert gas, or exhausting the inside of the processing chamber to a vacuum.

In accordance with the present invention, when a thin film including a metal is formed by the PE-ALD method wherein a film forming material and a reducing gas are alternately supplied, because the film forming material is dissociated by a plasma so that a precursor of the film-forming metal having a smaller molecular size reach the substrate, a larger amount of the film-forming metal can be adsorbed efficiently so that film forming rate can be improved. Further, because at least a part of the film forming material is dissociated in gaseous state by the plasma, the impurities in the film are decreased, and at the same time, the uniformity of the film-forming metal adsorbed on the substrate is improved, and the film quality and the film thickness uniformity of the thin film including the metal are improved. That is, due to a small amount of the impurities, a film having a low resistance can be formed finely and conformably. Further, because only the film forming material is dissociated in the plasma, the inside of the fine hole can be reached with ease, and the step coverage in the fine hole can be improved.

### BRIEF DESCRIPTION OF THE DRAWINGS

The above and other objects and features of the present invention will become apparent from the following description of preferred embodiments given in conjunction with the accompanying drawings, in which:

FIG. 1 offers a perspective block diagram schematically showing an internal cross section of an apparatus used in a film forming method of the present invention; and

FIG. 2 shows a timing chart showing an example of the film forming method of the present invention.

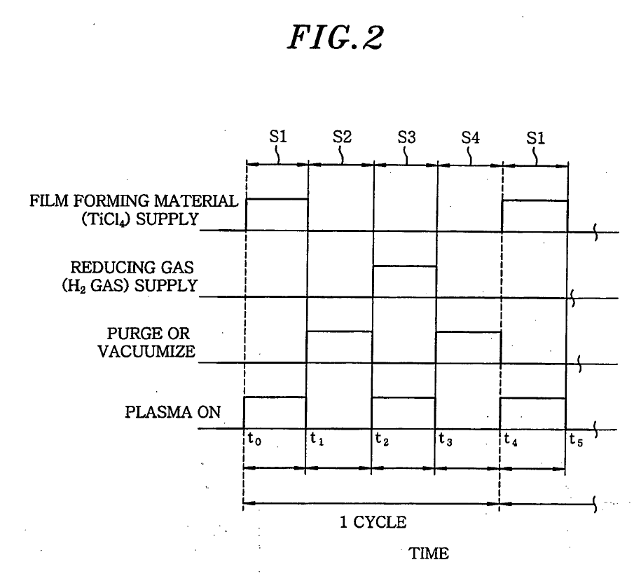

### DETAILED DESCRIPTION OF THE PREFERRED EMBODIMENTS

Hereinafter, various preferred embodiments of the present invention will be described with reference to the accompanying drawings.

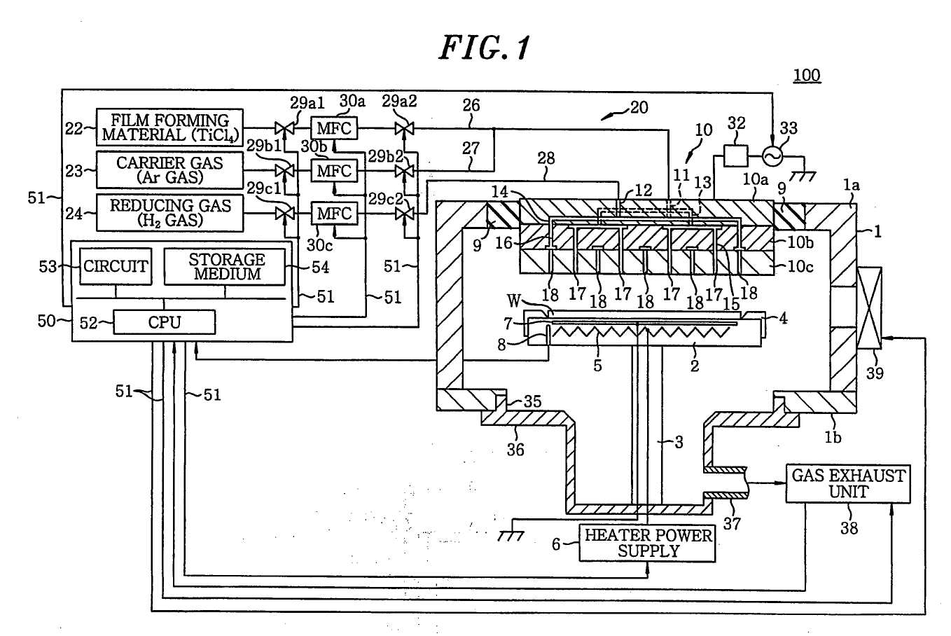

As shown in FIG. 1, each functional component of the film forming apparatus 100 in accordance with a preferred embodiment of the present invention is connected to a control computer 50 for automatically controlling an operation of the whole film forming apparatus via signal lines 51. Here, the functional components refer to all components operating to provide a predetermined film forming process condition to the film forming apparatus 100, including a heater power supply 6, valves 29a1 to 29c2, mass flow controllers (MFC's) 30a to 30c, a high frequency power supply 33, a gas exhaust unit 38, a gate valve 39, and other peripheral units. Herein, only a part of a plurality of signal lines 51 is shown for convenience. The control computer 50 is typically a general purpose computer capable of implementing various functions based on executable software.

The control computer 50 includes a central processing unit (CPU) 52, a circuit 53, and a storage medium 54. The circuit 53 includes a memory or a system bus for supporting the CPU. The storage medium 54 stores control software, wherein various process conditions (gas flow rates, pressure, temperature, high frequency power and the like) are customized according to standard specifications or particular customer requirements. The control computer 50 controls an operation of each functional component of the film forming apparatus 100 according to the control software stored in the storage medium 54.

The storage medium 54 may be fixedly provided to the control computer 50, or may be detachably attached to a reading device provided in the control computer 50 to be read by the reading device. Most typically, the storage medium 54 is a hard disk drive onto which the control software is installed by the film forming apparatus manufacturer. Further, the storage medium 54 may be a removable disk such as a CD-ROM or a DVD-ROM having the control software recorded thereon. This removable disk is read by an optical reading device provided to the control computer 50. The storage medium 54 may be provided in a form of either one of a ROM and a RAM, and may be a cassette type ROM or the like. In short, all storage media generally known in a field of a computer technology can be used as the storage medium 54. Further, in a factory having a plurality of film forming apparatuses, the control software may be stored in a system controller for generally controlling the control computer 50 of each film forming apparatus. In this case, each film forming apparatus is controlled by the system controller via a communication line to perform a predetermined process.

The film forming apparatus 100 is provided with an airtight chamber 1 of a substantially cylindrical shape with a susceptor 2 provided therein. The susceptor 2 is supported by a cylindrical supporting member 3 and a wafer W is horizontally mounted thereon. A guide ring 4 for guiding the wafer W is provided on an outer periphery portion of the susceptor 2.

A heater 5, a temperature sensor 8 and a lower electrode 7 are embedded in the susceptor 2. The heater 5 is connected to an output unit of the control computer 50 via a heater power supply 6. The temperature sensor 8 is connected to an input unit of the control computer 50. The lower electrode 7 is grounded. Once a detected temperature signal for the susceptor 2 (the wafer W, indirectly) is inputted from the temperature sensor 8 to the control computer 50, in response thereto, a control signal is transmitted from the control computer 50 to the heater power supply 6 to heat the wafer W on the susceptor 2 to a predetermined target temperature by the heater 5.

A shower head 10 is disposed in a ceiling wall 1a of the chamber 1 through an insulating member 9. An upper block body 10a, a middle block body 10b, and a lower block body 10c are stacked and integrated to form the shower head 10. The lower block body 10c is provided with a plurality of gas injection holes 17 and 18 alternately disposed therein. The gas injection holes 17 and 18 are extended through the lower block body 10c in a thickness direction to be opened at the bottom surface of the lower block body 10c.

A first gas inlet opening 11 and a second gas inlet opening 12 are opened at the top surface of the upper block body 10a. The first and the second gas inlet openings 11 and 12 communicate with gas lines 26 and 28 of a gas supply unit 20, respectively. A first branch flow path 13 is formed in the upper block body 10a. Further, a second branch flow path 15 is also formed in the middle block body 10b. These first and second branch flow paths 13 and 15 communicate with each other. The upper first branch flow path 13 communicates with the first gas inlet opening 11, and the lower second branch flow path 15 communicates with the gas injection holes 17 in the lower block body 10c.

Meanwhile, a third branch flow path 14 is formed in the upper block body 10a. Further, a fourth branch flow path 16 is formed also in the middle block body 10b. These third and fourth branch flow paths 14 and 16 communicate with each other. The upper third branch flow path 14 communicates with the second gas inlet opening 12, and the lower fourth branch flow path 16 communicates with the gas injection holes 18 in the lower block body 10c.

The gas supply unit 20 includes three supply sources 22 to 24. The first supply source 22 supplies a film forming material such as TiCl₄. The second supply source 23 supplies an inert gas such as Ar gas serving as a carrier gas. The third supply source 24 supplies a reducing gas such as H₂. A first gas line 26, a second gas line 27 and a third gas line 28 are connected to the first supply source 22, the second supply source 23 and the third supply source 24, respectively. The first gas line 26 is provided with the valve 29a1, the mass flow controller 30a and the valve 29a2 in that order from the upstream side thereof. The second gas line 27 is provided with the valve 29b1, the mass flow controller 30b and the valve 29b2 in that order from the upstream side thereof. The third gas line 28 is provided with the valve 29c1, the mass flow controller 30c and the valve 29c2 in that order from the upstream side thereof.

The first gas line 26 communicates with the first gas inlet opening 11. The second gas line 27 joins the first gas line 26 at an appropriate position. The control computer 50 controls the valves 29a1, 29a2, 29b1 and 29b2, and the MFC's 30a and 30b to regulate respective flow rates of the film forming material TiCl₄ and the carrier gas (Ar gas), allowing the film forming material to be joined and carried by the carrier gas. The film forming material TiCl₄, along with the carrier gas (Ar or the like), passes through the first gas line 26 to be introduced into the shower head 10 through the first gas inlet opening 11, and is uniformly injected through the gas injection holes 17 into the chamber 1 through the branch flow paths 13 and 15.

Meanwhile, the third gas line 28 communicates with the second gas inlet opening 12. The control computer 50 controls the valves 29c1 and 29c2, and the MFC 30c to regulate a flow rate of the reducing gas (H₂ gas). The reducing gas (H₂ gas) passes through the third gas line 28 to be introduced into the shower head 10 through the second gas inlet opening 12 of the shower head 10, and is uniformly injected through the gas injection holes 18 into the chamber 1 through the branch flow paths 14 and 16. In this way, the film forming material and the reducing gas are independently supplied into the chamber 1 through the shower head 10. Such kind of shower head 10 is called a post-mix type.

A high frequency power supply 33 is connected to the shower head 10 via a matching unit 32. The inert gas serving as the carrier gas for the film forming material, and the reducing gas, supplied into the chamber 1 through the shower head 10, are converted into plasma by a high frequency power from the high frequency power supply 33 being applied between the shower head 10 and the lower electrode 7.

A circular recess 35 is formed at a central portion of a bottom wall 1b of the chamber 1, and an exhaust chamber 36 protruding downward so as to cover the recess 35 is provided on the bottom wall 1b. A gas exhaust line 37 is connected to a side surface of the exhaust chamber 36, and a gas exhaust unit 38 is connected to the gas exhaust line 37. By operating the gas exhaust unit 38, it is possible to reduce a pressure in the chamber 1 to a predetermined vacuum level. A gate valve 39 is provided on a sidewall of the chamber 1, so that the wafer W can be loaded into and unloaded from the chamber 1 by opening the gate valve 39.

Hereinafter, a case where a Ti film is formed on a silicon wafer W by using the film forming apparatus will be described.

In forming the Ti film layer, TiCl₄ is used as the film forming material, the Ar gas is used as the carrier gas, and the H₂ gas is used as the reducing gas. First, the susceptor 2 is heated to a temperature of 150 to 600° C., preferably to a temperature of 400° C. or less by using the heater 5, and the chamber 1 is exhausted by the gas exhaust unit 38 to be maintained at a pressure of 13 to 1,330 Pa, preferably at a pressure of about 650 Pa. Under such state, the wafer W is loaded into the chamber 1 from outside after the gate valve 39 is opened.

At a time t₀, Ar serving as the carrier gas and TiCl₄ serving as the film forming material begin to be supplied into the chamber 1 at a flow rate of 10 to 5000 mL/min, preferably about 50 mL/min, and at a flow rate of 1 to 100 mL/min, preferably about 5 mL/min, respectively. At the same time, a high frequency power of 50 to 5000 W, for example about 100 W, from the high frequency power supply 33 is applied to the shower head 10 to form Ar gas plasma in the chamber 1 and to allow a metal precursor for use in forming the film, TiClₓ (x=1 to 3), to be uniformly adsorbed onto the entire surface of the wafer W (step S1). At a time t₁, a supply of the film forming material TiCl₄ is stopped and the high frequency power is turned off. It is preferable that duration for step S1, i.e., from t₀ to t₁, falls within a range of 0.1 to 5 seconds, and it was 3 seconds in this embodiment.

At the time t₁, the Ar gas begins to be supplied into the chamber 1 at a flow rate of 100 to 5000 mL/min, for example, at a flow rate of about 2000 mL/min to purge the inside of the chamber 1 with the Ar gas, thereby removing the residual film forming material in the chamber 1 (step S2). At a time t₂, the supply of the Ar gas is stopped. It is preferable that duration for step S2, i.e., from t₁ to t₂, falls within a range of 0.1 to 5 seconds, and it was 3 seconds in this embodiment. Further, instead of purging the inside of the chamber 1 with the Ar gas, a vacuum evacuation may be merely performed.

At the time t₂, H₂ gas serving as the reducing gas is supplied into the chamber 1 at a flow rate of 100 to 5000 mL/min, preferably about 1500 mL/min, and the Ar gas is supplied into the chamber 1 at a flow rate of 0 to 1000 mL/min. At the same time, by applying a high frequency power of 100 to 1000 W, for example about 350 W, from the high frequency power supply 33 to the shower head 10, H₂ as the reducing gas is converted into a plasma, allowing the metal precursor, such as TiClₓ (x=1 to 3) and the like adsorbed on the wafer W, to be reduced (step S3). At a time t₃, the supply of the reducing gas (H₂ gas) is stopped and the high frequency power is turned off. It is preferable that duration of step S3, i.e., from t₂ to t₃, falls within in a range of 0.1 to 10 seconds, and it was 10 seconds in this embodiment.

At the time t₃, the supply of the reducing gas (H₂ gas) is stopped, and only the Ar gas serving as the carrier gas is supplied into the chamber 1 at a flow rate of 100 to 5000 mL/min, for example, at a flow rate of about 2000 mL/min, thereby purging the inside of the chamber 1 to remove the residual reducing gas therein (step S4). At a time t₄, the supply of the Ar gas is stopped. It is preferable that duration of step S4, i.e., from t₃ to t₄, falls within a range of 0.1 to 5 seconds, and it was 3 seconds in this embodiment. Further, instead of purging the inside of the chamber 1 with the Ar gas, a vacuum evacuation may be carried out only.

The above-described steps S1 through S4 are repeatedly performed until a thickness of the Ti film formed on the wafer W reaches a predetermined target value. Accordingly, a Ti film having a film thickness of, for example, 2 to 20 nm can be obtained.

In the method of the preferred embodiment as described above, the Ar gas, which is an inert gas, is converted into plasma in the chamber 1 during step S1, causing at least a part of the film forming material, TiCl₄, to dissociate while it is in a gaseous state, thereby allowing the film forming material to reach the wafer W not as TiCl₄ having a large molecular size but as the metal precursor, i.e., TiClₓ (x=1 to 3). Therefore, a ratio of Ti to other substances adsorbed on the wafer W can be increased without obstructing adsorption sites on wafer W, and separation of TiClₓ (x=1 to 3) generated by the plasma becomes difficult. As a result, the film forming rate can be increased and a film forming throughput can be improved. Moreover, because at least a part of TiCl₄ is dissociated in gaseous state by the plasma, the penetration of Cl⁻ (minus ion), which is a bi-product of the dissociation, into the film is suppressed, which, in turn, reduces impurities such as Cl in the film. Further, because the metal precursor, TiClₓ (x=1 to 3), has been dissociated by the plasma and is volumetrically smaller, it can be more densely adsorbed on the wafer W, improving a uniformity of the film-forming metal adsorbed on the wafer W. As a result, a film quality and a film thickness uniformity of the Ti film are improved. That is, an amount of the impurities is small so that a Ti film having a low resistance can be formed finely and conformably. Further, because only TiClₓ (x=1 to 3), which is obtained by dissociating at least a part of TiCl₄, is supplied separately from the reducing gas and adsorbed on the wafer W, inner parts of fine holes can be easily reached, thus improving the step coverage.

Additionally, in the conventional PE-ALD method, TiCl₄ is transported onto a wafer W in a (volumetrically large) molecular state without being dissociated, which, in turn, will obstruct the adsorption site and cause the amount of TiCl₄ adsorbed on the wafer W to decrease. In contrast, in accordance with the preferred embodiment of the present invention, because a part of TiCl₄ is dissociated by igniting the plasma of the Ar gas and TiClₓ (x=1 to 3) is adsorbed on the wafer W, the above-described problem does not occur, so that the throughput of the film forming process is improved and the film quality and the film thickness uniformity are also improved. Further, the step coverage of the fine hole becomes better than a case where TiCl₄ and the reducing gas are simultaneously converted into plasma and supplied.

Further, in case of dissociating TiCl₄ thermally, a low temperature film forming is difficult because TiCl₄ does not readily dissociate if the temperature is not a high level equal to or greater than 500° C. and further because, at a low temperature, a concentration of the impurities such as Cl or the like is high which results in a high film resistance and those impurities corrode wiring materials, e.g., Al and Cu. However, in case of dissociating TiCl₄ by the plasma as in the preferred embodiment of the present invention, because it is dissociated at a lower temperature, the low temperature film forming is possible, and a film having a low resistance and of high quality can be formed without thermally influencing the wiring materials or elements (Thermal Budget). That is, because the low temperature film forming is possible in accordance with the present invention, an amount of a generated heat (=temperature×time) is not great enough to influence the wiring materials or elements, allowing a film layer having a low resistance and of a high quality to be formed.

Further, the present invention is not limited to the above-described preferred embodiment, and various changes and modifications may be made thereto. For example, the time at which the film forming material is supplied in step S1 may be changed, for example, to before the plasma of the inert gas such as Ar or the like is ignited, when the plasma is ignited, or after the plasma is ignited. Further, various combinations of a gas flow rate of the inert gas such as Ar or the like and a plasma power may be chosen depending on the kind of the film forming material.

Furthermore, although the above preferred embodiment has been described with reference to the case where TiCl₄ and H₂ are used to form the Ti film as an example, other combination of gases may be used, and the present invention can also be applied in forming a TiN film, a W film, a WN film, a TaN film and a TaCN film.

In forming the Ti film or the TiN film, one or more materials selected from the group consisting of TiCl₄, TiF₄, TiBr₄, TiI₄, Ti[N(C₂H₅CH₃)]₄ (TEMAT), Ti[N(CH₃)₂]₄ (TDMAT) and Ti[N(C₂H₅)₂]₄ (TDEAT) may be used as a film forming material including Ti, and one or more gases selected from the group consisting of H₂, NH₃, N₂H₄, NH(CH₃)₂, N₂H₃CH₃ and N₂ may be used as the reducing gas.

In forming the W film or the WN film, WF₆ and W(CO)₆ may be used as a film forming material including W, and one or more gases selected from the group consisting of H₂, NH₃, N₂H₄, NH(CH₃)₂, N₂H₃CH₃ and N₂ may be used as the reducing gas.

In forming the Ta, TaN or TaCN film, one or more materials selected from the group consisting of TaCl₅, TaF₅, TaBr₅, TaI₅, Ta(NC(CH₃)₃), (N(C₂H₅)₂)₃ (TBTDET) and Ta(NC(CH₃)2C₂H₅) (N(CH₃)₂)₃ may be used as a film forming material including Ta, and one or more gases selected from the group consisting of H₂, NH₃, N₂H₄, NH(CH₃)₂, N₂H₃CH₃ and N₂ may be used as the reducing gas.

When supplying these reducing gases, a combination of a plurality of reducing gases may be used.

Further, although the preferred embodiment of the present invention has been described with reference to the case where a capacitively coupled high frequency plasma source of a parallel plate type is used, the present invention is not limited thereto. The present invention may be applied to, for example, an Inductively Coupled Plasma generating apparatus (ICP), an ECR (Electron Cyclotron Resonance) type plasma generating apparatus, or an RLSA (Radial Line Slot Antenna) microwave generating apparatus.

While the present invention has been described with respect to the particular embodiments, it will be apparent to those skilled in the art that various changes and modifications may be made without departing from the spirit and scope of the invention as defined in the following claims.

What is claimed is:

1. A film forming method for forming a thin film including a metal on a substrate by alternately supplying the substrate with a film forming material including the metal and a reducing gas, wherein at least a part of the film forming material is dissociated or decomposed in gaseous state by a plasma and is supplied onto the substrate.

2. The film forming method of claim 1, wherein the reducing gas is converted into the plasma when the reducing gas is supplied onto the substrate.

3. The film forming method of claim 1, wherein the plasma for dissociating or decomposing at least a part of the film forming material is a plasma of an inert gas.

4. The film forming method of claim 1, wherein, after the film forming material is supplied onto the substrate, and after the reducing gas is supplied onto the substrate, the surplus film forming material and the reducing gas are removed from a top surface of the substrate.

5. The film forming method of claim 1, wherein the film forming material includes one or more materials selected from the group consisting of TiCl₄, TiF₄, TiBr₄, TiI₄, Ti[N(C₂H₅CH₃)]₄ (TEMAT), Ti[N(CH₃)₂]₄ (TDMAT) and Ti[N(C₂H₅)₂]₄ (TDEAT), and the reducing gas includes one or more gases selected from the group consisting of H₂, NH₃, N₂H₄, NH(CH₃)₂, N₂H₃CH₃ and N₂, to form a Ti film or a TiN film on the substrate.

6. The film forming method of claim 1, wherein the film forming material includes at least one material of WF₆ and W(CO)₆, and the reducing gas includes one or more gases selected from the group consisting of H₂, NH₃, N₂H₄, NH(CH₃)₂, N₂H₃CH₃ and N₂, to form a W film or a WN film on the substrate.

7. The film forming method of claim 1, wherein the film forming material includes one or more materials selected from the group consisting of TaCl₅, TaF₅, TaBr₅, TaI₅, Ta(NC(CH₃)₃), (N(C₂H₅)₂)₃(TBTDET) and Ta(NC(CH₃)₂C₂H₅) (N(CH₃)₂)₃, and the reducing gas includes one or more gases selected from the group consisting of H₂, NH₃, N₂H₄, NH(CH₃)₂, N₂H₃CH₃ and N₂, to form any one of a Ta film, a TaN film or a TaCN film on the substrate.

8. A film forming method for forming a thin film including a metal on a substrate in a processing chamber, comprising the steps of;
(a) supplying a film forming material including the metal to the substrate;
(b) removing a residual gas in the processing chamber after the supply of the film forming material is stopped;
(c) supplying a reducing gas to the substrate in the processing chamber; and
(d) removing a residual gas in the processing chamber after the supply of the reducing gas is stopped,
wherein the thin film is formed by repeatedly performing the steps (a) to (d),
and, in the step (a), at least a part of the film forming material is dissociated or decomposed in gaseous state by a plasma and supplied onto the substrate.

9. The film forming method of claim 8, wherein, in the step (c), the reducing gas is converted into the plasma when the reducing gas is supplied onto the substrate.

10. The film forming method of claim 8, wherein, in the step (a), the plasma for dissociating or decomposing at least a part of the film forming material is a plasma of an inert gas.

11. The film forming method of claim 8, wherein, in the step (b) and the step (d), an atmosphere in the processing chamber is replaced with an inert gas, or the inside of the processing chamber is exhausted to a vacuum.

12. The film forming method of claim 8, wherein the film forming material includes one or more materials selected from the group consisting of TiCl₄, TiF₄, TiBr₄, TiI₄, Ti[N(C₂H₅CH₃)]₄ (TEMAT), Ti[N(CH₃)₂]₄ (TDMAT) and Ti[N(C₂H₅)₂]₄ (TDEAT), and the reducing gas includes one or more gases selected from the group consisting of H₂, NH₃, N₂H₄, NH(CH₃)₂, N₂H₃CH₃ and N₂, to form a Ti film or a TiN film on the substrate.

13. The film forming method of claim 8, wherein the film forming material includes at least one or more materials of WF₆ and W(CO)₆, and the reducing gas includes one or more gases selected from the group consisting of H₂, NH₃, N₂H₄, NH(CH₃)₂, N₂H₃CH₃ and N₂, to form a W film or a WN film on the substrate.

14. The film forming method of claim 8, wherein the film forming material includes one or more materials selected from the group consisting of TaCl₅, TaF₅, TaBr₅, TaI₅, Ta(NC(CH₃)₃), (N(C₂H₅)₂)₃ (TBTDET) and Ta(NC(CH₃)₂C₂H₅) (N(CH₃)₂)₃, and the reducing gas includes one or more gases selected from the group consisting of H₂, NH₃, N₂H₄, NH(CH₃)₂, N₂H₃CH₃ and N₂, to form any one of a Ta film, a TaN film or a TaCN film on the substrate.

15. A computer storage medium storing a software executable by a computer system, wherein, when a thin film including a metal is formed on a substrate by repeating the following steps of;
(a) supplying a film forming material including the metal to the substrate in a processing chamber;
(b) removing a residual gas in the processing chamber after a supply of the film forming material is stopped;
(c) supplying a reducing gas to the substrate in the processing chamber; and
(d) removing a residual gas in the processing chamber after the supply of the reducing gas is stopped,
the software controls a gas plasma in the processing chamber so that at least a part of the film forming material is dissociated or decomposed in gaseous state by the plasma and supplied onto the substrate in the step (a).
